(19) United States
(12) Patent Application Publication
(10) Pub. No.: US 2013/0327568 A1
(43) Pub. Date: Dec. 12, 2013

(54) ELECTRONIC DEVICE HOUSING

(71) Applicants: MING-HSIEN WANG, New Taipei City (TW); HSIENG-JAN WENG, Taipei City (TW)

(72) Inventors: MING-HSIEN WANG, New Taipei City (TW); HSIENG-JAN WENG, Taipei City (TW)

(73) Assignee: ASKEY COMPUTER CORP.

(21) Appl. No.: 13/562,905

(22) Filed: Jul. 31, 2012

(30) Foreign Application Priority Data
Jun. 7, 2012 (TW) 101211008

(51) Int. Cl. H05K 5/02; H05K 5/00

(52) U.S. Cl. 174/565; 174/520

(57) ABSTRACT

An electronic device housing internally defines a receiving space for accommodating a circuit board and electronic elements mounted on the circuit board, and has a thermal insulation layer provided on an inner surface thereof at a position corresponding to the circuit board. The thermal insulation layer provided on the inner surface of the electronic device housing not only suppresses and prevents flames produced by, for example, the spontaneous combustion of the electronic elements in the housing from spreading to and endangering the environment surrounding the electronic device, but also enables reduced product weight and manufacturing cost of the electronic device.

### CROSS-REFERENCE TO RELATED APPLICATION

This non-provisional application claims priority under 35 U.S.C. §119(a) on Patent Application No(s). 101211008 filed in Taiwan, R.O.C. on Jun. 7, 2012, the entire contents of which are hereby incorporated by reference.

### FIELD OF TECHNOLOGY

The present invention relates to a housing, and more particularly to an electronic device housing.

### BACKGROUND

FIG. 1 schematically shows an electronic device 6 that internally has a circuit board 2 with electronic elements mounted thereon. Since a heat-producing electronic element on the circuit board 2 is subject to spontaneous combustion, which would possibly cause a fire to endanger the life and property safety of the general public or peripheral devices surrounding the electronic device 6, it is required the electronic device 6 must pass a flammability test to ensure its safety in use before it is allowed for delivery and selling. According to the prior art, the electronic device 6 includes a housing having a metal shielding case 4 provided therein. The metal shielding case 4 is used not only to prevent electromagnetic interference (EMI), but also to block flames produced during the flammability test or by the spontaneous combustion of the heat-producing electronic elements, so that the flames are prevented from spreading to and endangering the environment surrounding the electronic device 6.

The metal shielding case 4 requires considerably high designing and mold-making costs, and tends to cause short circuit when its metal material is in contact with the electronic elements. The heavy metal material of the metal shielding case 4 also disadvantageously increases the product weight and tends to rust.

It is therefore tried by the inventor to develop an improved electronic device housing for preventing flames produced by the electronic elements in the housing from spreading to and endangering the environment surrounding the electronic device.

### SUMMARY

A primary object of the present invention is to provide an electronic device housing that is able to prevent flames produced by the electronic elements in the housing from spreading to and endangering the environment surrounding the electronic device.

To achieve the above and other objects, the electronic device housing according to the present invention internally defines a receiving space for accommodating a circuit board and electronic elements mounted on the circuit board, and includes a thermal insulation layer provided on an inner surface of the housing at a position corresponding to the circuit board.

According to an embodiment of the present invention, the housing includes a first housing and a second housing closed onto and connected to the first housing. And, the thermal insulation layer is provided on an inner surface of at least one of the first and the second housing.

According to an embodiment of the present invention, the thermal insulation layer can be a fire-resistant fabric, a type of fire-resistant foam, or a fire-resistant rubber pad.

According to an embodiment of the present invention, the housing further includes a binding layer provided between the housing and the thermal insulation layer for binding the thermal insulation layer to the inner surface of the housing.

According to an embodiment of the present invention, the binding layer is an adhesive.

According to an embodiment of the present invention, the thermal insulation layer can be a graphite sheet, a mica sheet or a gypsum sheet.

According to an embodiment of the present invention, the housing further includes a stopper for partitioning the receiving space in the housing.

According to an embodiment of the present invention, the thermal insulation layer has a thickness ranged between 0.5mm and 5mm.

Compared to the conventional electronic device housing, the electronic device housing of the present invention having a thermal insulation layer provided on an inner surface thereof can effectively prevent flames produced by the electronic elements in the housing from spreading to and endangering the environment surrounding the electronic device.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an exploded perspective view of a conventional electronic device housing, in which a metal shielding case is also used for fire-retarding purpose;

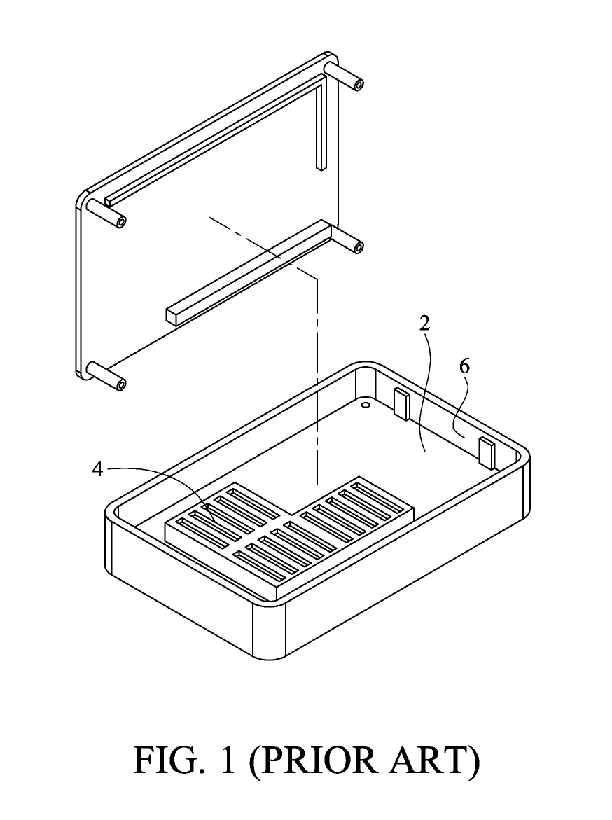

FIG. 2 is a partially exploded perspective view of an electronic device housing according to a first embodiment of the present invention;

FIG. 3 is a further exploded view of FIG. 2;

FIG. 4 is an exploded perspective view of an electronic device housing according to a second embodiment of the present invention;

FIG. 5 is an exploded perspective view of an electronic device housing according to a third embodiment of the present invention; and

FIG. 6 is an exploded perspective view of an electronic device housing according to a fourth embodiment of the present invention.

### DETAILED DESCRIPTION

The present invention will now be described with some preferred embodiments thereof and with reference to the accompanying drawings. For the purpose of easy to understand, elements that are the same in the preferred embodiments are denoted by the same reference numerals.

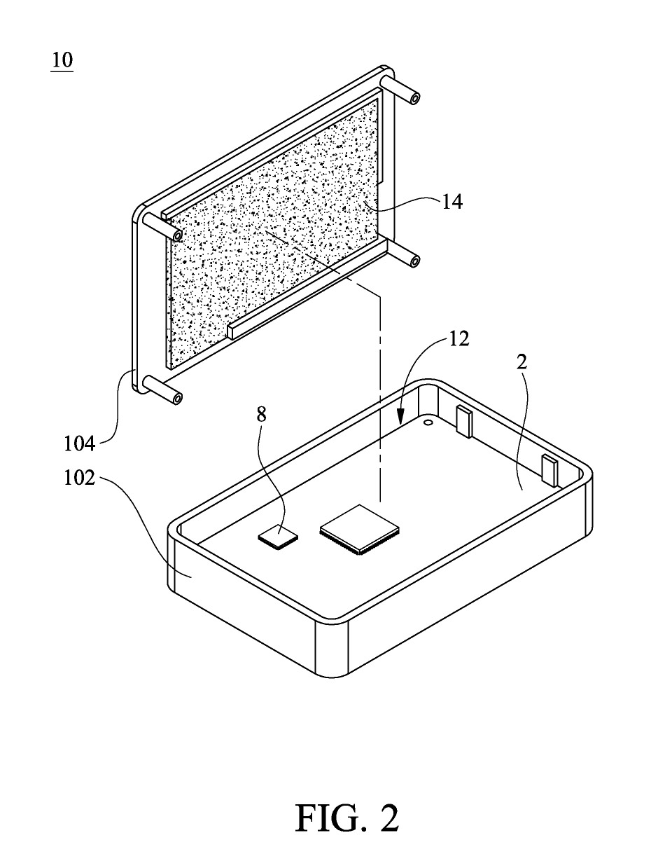

Please refer to FIG. 2 that is a partially exploded perspective view of an electronic device housing 10 according to a first embodiment of the present invention. As shown, the electronic device housing 10 in the first embodiment internally defines a receiving space 12 for accommodating a circuit board 2 and electronic elements 8 mounted on the circuit board 2. The housing 10 is characterized in that it includes a thermal insulation layer 14 provided on an inner surface thereof at a position generally corresponding to the circuit board 2. The housing 10 also functions to block flames due to spontaneous combustion of a heat-producing electronic element 8 on the circuit board 2, lest the flames should spread to the space outside the housing 10.

In the first embodiment, the housing 10 is illustrated as including a first housing 102 and a second housing 104 closed onto and connected to the first housing 102. The thermal insulation layer 14 may be provided on an inner surface of at least one of the first and the second housing 102, 104. For example, the housing 10 may be one for a network communication product, an electric appliance or any other electronic product. The housing for the network communication product or the electric appliance is usually made of a plastic material or a metal material. In the first embodiment, the housing is illustrated as a plastic housing.

The thermal insulation layer 14 is characterized in its high burning point as well as its flame-retarding and heat-resistant properties. In the illustrated first embodiment, the thermal insulation layer 14 is provided on the inner surface of the second housing 104 of the housing 10. When the second housing 104 is closed onto and connected to the first housing 102 that has the circuit board 2 provided therein, the thermal insulation layer 14 also covers the circuit board 2. In case of a burning electronic element 8 on the circuit board 2, the thermal insulation layer 14 is able to retard the upward flames from spoiling or burning through the second housing 104, and accordingly prevents the flames from spreading to the environment surrounding the electronic device to endanger the life and property safety of the general public to thereby achieve the fire prevention effect.

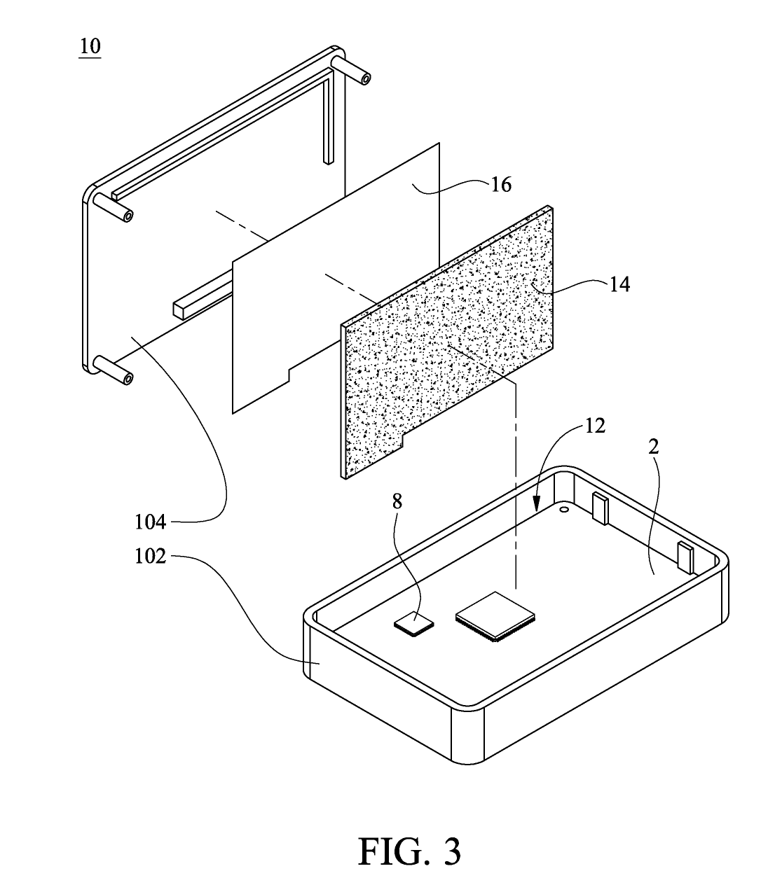

FIG. 3 is a further exploded perspective view of the electronic device housing 10. As can be seen in FIG. 3, the housing 10 further includes a binding layer 16 provided between the inner surface of the second housing 104 and the thermal insulation layer 14 for firmly binding the thermal insulation layer 14 to the housing 10. The binding layer 16 may be, for example, a back adhesive, a double-sided adhesive, or any other sticky binding material provided on one side of the thermal insulation layer 14 facing toward the inner surface of the second housing 104. In the first embodiment, the binding layer 16 is illustrated as a layer of back adhesive.

According to the present invention, the thermal insulation layer 14 may be a fire-resistant fabric, a type of fire-resistant foam, or a fire-resistant rubber pad. In the first embodiment, the thermal insulation layer 14 is illustrated as a fire-resistant fabric with the binding layer 16 provided on one side thereof in advance. With the binding layer 16, a user may directly apply the fire-resistant fabric to the inner surface of the second housing 104 corresponding to the contour thereof Further, the thermal insulation layer 14 may have a shape, a size and a thickness not necessarily limited to those shown in the first embodiment and the drawings. For example, the thermal insulation layer may have a thickness ranged between 0.5 mm and 5 mm, and may be changed in design according to different fire-prevention requirement of the inner surface of the electronic device housing. Any thermal insulation layer that satisfies the fire-prevention requirement of an electronic device shall fall in the scope of the present invention.

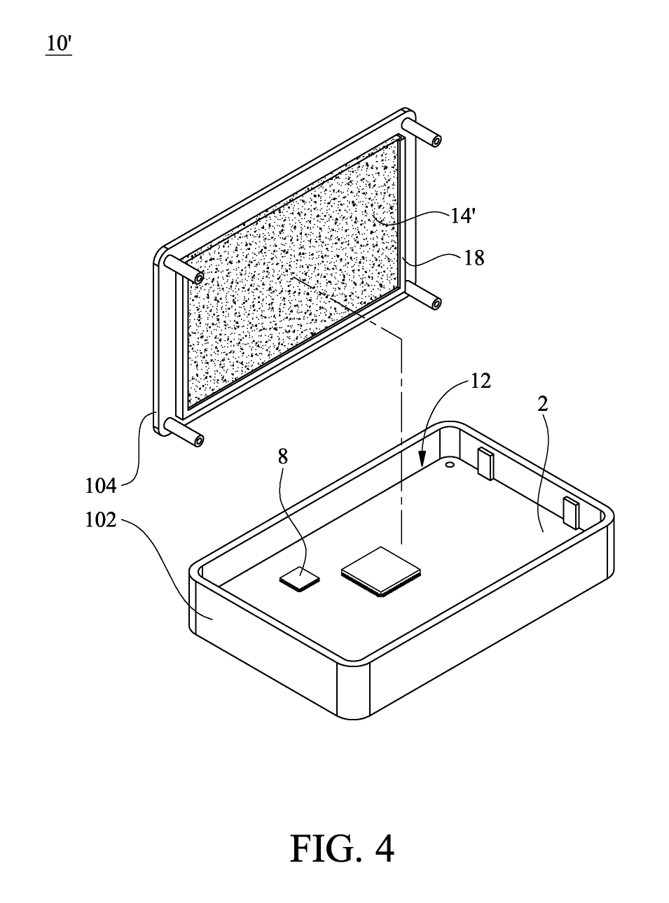

Please refer to FIG. 4 that is an exploded perspective view of an electronic device housing 10′ according to a second embodiment of the present invention that includes a thermal insulation layer 14′. The second embodiment is different from the first embodiment in that the second housing 104 thereof further includes a fastening element 18 provided on the inner surface of the second housing 104. The thermal insulation layer 14′ is connected to the housing 10′ via the fastening element 18. In the illustrated second embodiment, the thermal insulation layer 14′ is connected to the second housing 104 via the fastening element 18.

According to the present invention, the thermal insulation layer 14′ can be a graphite sheet, a mica sheet or a gypsum sheet; and the fastening element 18 may have a structure not necessarily limited to that shown in FIG. 4. For instance, the housing 10′ may be formed on its inner surface with a recess, in which the thermal insulation layer 14′ may be set to firmly associate with the housing 10′.

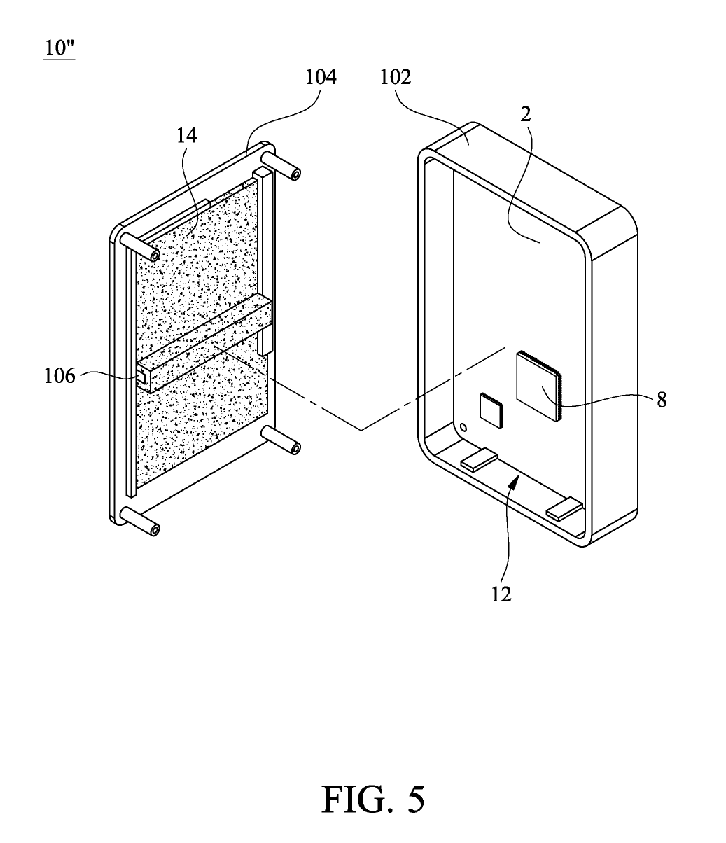

Please refer to FIG. 5 that is an exploded perspective view of an electronic device housing 10″ according to a third embodiment of the present invention that includes a thermal insulation layer 14. The third embodiment is different from the first embodiment in that the housing 10″ further includes a stopper 106 provided on the second housing 104 of the housing 10″. As can be seen in FIG. 5, the stopper 106 is located across a middle portion of the inner surface of the second housing 104 for supporting part of the thermal insulation layer 14 thereon and for dividing the receiving space 12 into a plurality of sub-spaces after the second housing 104 is closed onto the first housing 102, such that a heat-producing electronic element 8 is located in one of the sub-spaces. In this manner, in case of spontaneous combustion of the heat-producing electronic element 8, the flames are stopped from spreading out of the sub-space defined by the stopper 106. In other words, when the second housing 104 is closed onto and connected to the first housing 102, the stopper 106 forms a partition in the housing 10″ to serve as a flame-retardant wall capable of preventing flames from spreading to every corner in the housing 10″. Particularly, when the electronic device is configured for use in an upright position as shown in FIG. 5, flames produced by the heat-producing electronic element 8 mounted on the circuit board 2 and located in a sub-space below the stopper 106 can be prevent from spreading upward to burn through the housing 10″ at areas that are not covered by the thermal insulation layer 14.

In the third embodiment, the stopper 106 is illustrated as being formed by a sheet material. However, it is understood the stopper 106 may have shape and size and location not necessarily limited to those shown in FIG. 5. That is, the stopper 106 may be otherwise in the form of a block or be a particularly configured partition formed according to the arrangement of the electronic elements 8 on the circuit board 2. Further, the stopper 106 may be changed according to the exact areas that require fire protection and according to the required fire-resistance rating for the electronic device.

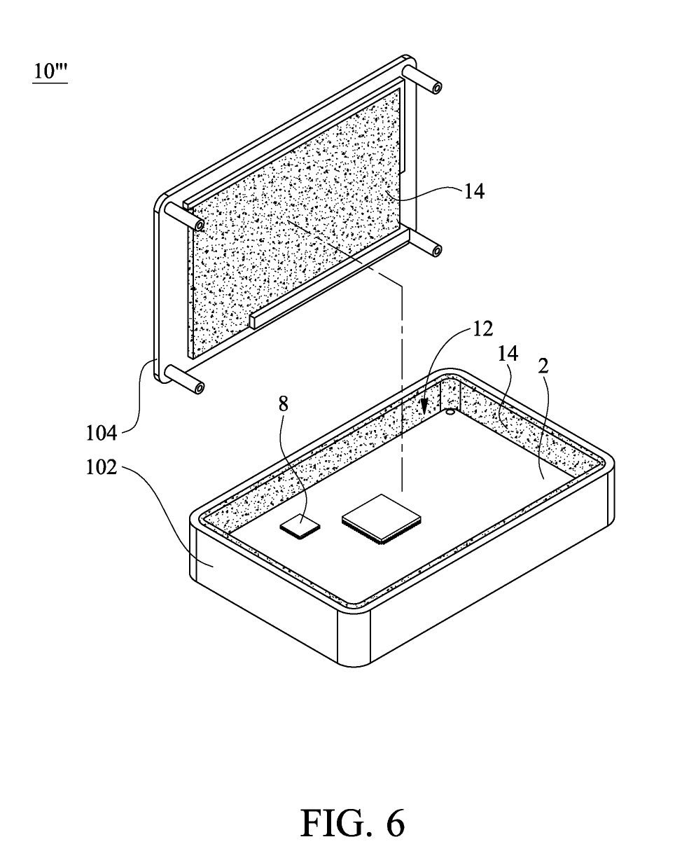

FIG. 6 is an exploded perspective view of an electronic device housing 10″' according to a fourth embodiment of the present invention that includes a thermal insulation layer 14. The fourth embodiment is different from the first embodiment in that the thermal insulation layer 14 is further provided on the inner surface of the first housing 102. That is, in the fourth embodiment, the thermal insulation layer 14 is provided on the inner surfaces of both the first and the second housing 102, 104 to provide the electronic device housing with enhanced fire-retardant effect.

Moreover, in another embodiment not shown in the drawings, the first and the second housing 102, 104 are provided on their entire inner surfaces with the thermal insulation layer 14, so that the circuit board 2 is completely enclosed in the thermal insulation layer 14. Meanwhile, when the first housing 102 is provided with heat-dissipating vents, the thermal insulation layer 14 is provided with openings corresponding to the heat-dissipating vents. Alternatively, the thermal insulation layer 14 is formed corresponding to the housing, allowing the heat-dissipating vents to communicate with the receiving space in the housing. In this manner, the electronic device housing is able to achieve flame-retarding and heat-dissipating functions at the same time.

All kinds of electronic device housings must be subjected to a flammability test. For instance, for an electronic device that is a network communication product to be sold in northern American countries, it must pass the requirements specified by the Network Equipment Building Systems (NEBS). Results from tests conducted on the conventional electronic device housing and the electronic device housing of the present invention according to the fireproof and flame-retardant requirements under NEBS GR-63-CORE indicate that the conventional electronic device housing using a metal shielding case for fire retarding has a fire-retardant performance value about 60% only and becomes deformed under the test without satisfying the NEBS requirements, while the electronic device housing according to the present invention has a fire-retardant performance value higher than 90% and is not deformed under the test. Therefore, the electronic device housing of the present invention is proven to have largely upgraded fire-retardant ability and fully satisfy the NEBS requirements.

Compared to the conventional electronic device housing, the electronic device housing of the present invention including a thermal insulation layer provided on an inner surface thereof can effectively suppress and prevent flames produced by the electronic elements in the housing from spreading to and endangering the environment surrounding the electronic device, and the thermal insulation layer is lightweight and low in price to enable reduced product weight and manufacturing cost of the electronic device.

The present invention has been described with some preferred embodiments thereof and it is understood that many changes and modifications in the described embodiments can be carried out without departing from the scope and the spirit of the invention that is intended to be limited only by the appended claims.

What is claimed is:

1. An electronic device housing, comprising a housing internally defining a receiving space for accommodating a circuit board and electronic elements mounted on the circuit board, and a thermal insulation layer provided on an inner surface of the housing at a position corresponding to the circuit board.

2. The electronic device housing as claimed in claim 1, wherein the housing includes a first housing and a second housing closed onto and connected to the first housing; and the thermal insulation layer being provided on an inner surface of at least one of the first and the second housing.

3. The electronic device housing as claimed in claim 1, wherein the thermal insulation layer is selected from the group consisting of a fire-resistant fabric, a type of fire-resistant foam, and a fire-resistant rubber pad.

4. The electronic device housing as claimed in claim 1, further comprising a binding layer being provided between the housing and the thermal insulation layer for binding the thermal insulation layer to the inner surface of the housing.

5. The electronic device housing as claimed in claim 4, wherein the binding layer is an adhesive.

6. The electronic device housing as claimed in claim 1, further comprising a fastening element for holding and connecting the thermal insulation layer to the inner surface of the housing.

7. The electronic device housing as claimed in claim 6, wherein the thermal insulation layer is selected from the group consisting of a graphite sheet, a mica sheet, and a gypsum sheet.

8. The electronic device housing as claimed in claim 1, further comprising a stopper for partitioning the receiving space in the housing.

9. The electronic device housing as claimed in claim 1, wherein the thermal insulation layer has a thickness ranged between 0.5 mm and 5 mm.
